(19) United States
(12) Patent Application Publication
(10) Pub. No.: US 2006/0043603 A1
(43) Pub. Date: Mar. 2, 2006

(54) Low temperature PB-free processing for semiconductor devices

(75) Inventors: Yogendra Ranade, Fremont, CA (US); Rajagopalan Parthasarathy, Milpitas, CA (US); Jeffrey Allan Hall, San Jose, CA (US)

Correspondence Address: LSI LOGIC CORPORATION, 1621 BARBER LANE, MS: D-106, MILPITAS, CA, 95035, US

(73) Assignee: LSI Logic Corporation, Milpitas, CA (US)

(21) Appl. No.: 10/932,174

(22) Filed: Aug. 31, 2004

(51) Int. Cl. H01L 21/44; H01L 23/48

(52) U.S. Cl. 257/778; 438/108; 257/779; 438/612; 257/782

(57) ABSTRACT

Techniques for utilizing a bonding agent that allows a solder reflow process to occur at a lower reflow temperature. One area of use includes semiconductor device manufacturing processes. The bonding agent is placed between a solder ball and a contact surface. The bonding agent has a melting temperature that is lower than that of the solder ball. Reflow is then performed at a relative low temperature that is high enough for reflowing the bonding agent, yet at the same time, lower than what would be necessary to reflow the solder material. Since, the electrical system is not subjected to the high temperatures necessary for reflowing the solder material, the electronic system experiences less high-temperature related damage.

### FIELD OF THE INVENTION

The present invention relates generally to soldering techniques for electronic devices, and more specifically to lower-temperature soldering processes.

### BACKGROUND

The electronics industry is turning towards lead-free components to reduce hazardous conditions related to electronic devices that incorporate lead components. A common component of the electronics industry is solder material, commonly used in the form of solder balls. Solder balls that contain lead are being replaced by lead-free materials such as, but not limited to, tin, silver, copper, and alloys of such materials such as a tin/silver/copper alloy (Sn/Ag/Cu). These new solder materials are safer for the environment and for electronic device users, however, they present new challenges in areas such as manufacturing.

One manufacturing challenge presented by the new materials relates to their high melting temperatures. For example, Sn/Ag/Cu alloys typically have melting temperatures that are higher than the melting temperatures of the well-known lead containing solder balls. A typical lead-free solder material has a melting temperature around approximately 220° C. Reflow temperatures above approximately 250° C. are necessary to bond such a solder ball to a contact surface. Such high temperatures are typically above the glass transition temperature, T_{g}, of one or more of the components that make up a semiconductor device to which a solder ball is attached. Unfortunately, these components become unworkably soft at such elevated temperatures. Also, differences between the coefficients of thermal expansion of the various components within a semiconductor device can already lead to structural separation of the components due to each component's respective rate of expansion or contraction. However, the elevated temperatures required to reflow the lead-free solder balls exacerbates this problem.

A current solution to minimize the problems of reflowing lead-free solder balls at high temperatures uses underfill materials. For example, an underfill material can fill the voids between multiple solder balls, which connect a semiconductor device and a substrate. Such a semiconductor device can be for example a flip chip or a ball grid array semiconductor device package. The underfill material protects the combination of the semiconductor device and the substrate by holding the combination in place with respect to each other. At the same time, the underfill material protects the solder balls from cycling fatigue. To be effective underfill, should have a relatively high modulus of elasticity for stiffness that it can take up some of the strains during cycling. At the same time, however, the underfill desirably has a relatively low modulus of elasticity so that it is sufficiently pliable to remain in contact with the device and the substrate during the high temperature reflow process. It is easy to see how these contrasting and ideal characteristics make it difficult to find an effective underfill.

In view of the foregoing, there are continuing efforts to provide improved techniques for reflowing lead-free solder balls in electronic devices.

### BRIEF SUMMARY OF THE INVENTION

The present invention is directed to a bonding agent that allows a solder reflow process to occur at a lower reflow temperature. One area of use includes semiconductor device manufacturing processes where solder materials having high melting temperatures require reflowing. The bonding agent is placed between a solder ball, for example, and a contact surface. The bonding agent is selected to have a melting temperature that is lower than that of the solder ball. Reflow is then performed at a relative low temperature that is high enough for reflowing the bonding agent, yet at the same time, lower than what would be necessary to reflow the solder material. Since, the electrical system is not subjected to the high temperatures necessary for reflowing the solder material, the electronic system experiences less high-temperature related damage.

As an apparatus, one embodiment of the present invention includes at least a substrate having contact pads and conductive traces, at least some of the contact pads being connected to a respective conductive trace, a bonding agent formed upon at least some of the contact pads, each bonding agent having a bonding agent melting temperature, and a semiconductor device having a plurality of solder balls, each of the solder balls being attached to a respective bonding agent wherein each bonding agent bonds a solder ball to a contact pad and wherein each of the solder balls has a solder melting temperature that is higher than the bonding agent melting temperature.

In an alternative embodiment of the invention, an apparatus includes at least a first substrate having contact pads and conductive traces formed upon a first surface and an opposing second surface, at least some of the contact pads being connected to a respective conductive trace, a bonding agent formed upon at least some of the contact pads of the first and the second surface of the first substrate, each of the bonding agents having a bonding agent melting temperature, a semiconductor device having a plurality of solder balls, each of the solder balls being attached to a respective bonding agent on the first surface of the first substrate wherein each bonding agent bonds a solder ball to a contact pad, and a second substrate having a plurality of solder balls, each of the solder balls being attached to a respective bonding agent on the second surface of the first substrate wherein each bonding agent bonds a solder ball to a contact pad. The solder balls of the semiconductor device and the second substrate have a solder melting temperature that is higher than the bonding agent melting temperature.

In yet another embodiment of the invention, an apparatus includes at least a first electrical device having contact pads and conductive traces, at least some of the contact pads being connected to a respective conductive trace, a bonding agent formed upon at least some of the contact pads of the first electrical device, each bonding agent having a bonding agent melting temperature, and a second electrical device having a plurality of solder balls, each of the solder balls being attached to a respective bonding agent wherein each bonding agent bonds a solder ball to a contact pad of the first electrical device and wherein each of the solder balls has a solder melting temperature that is higher than the bonding agent melting temperature.

As a method, one embodiment of the present invention includes at least providing a substrate having contact pads and conductive traces, at least some of the contact pads being connected to a respective conductive trace, applying a bonding agent upon at least some of the contact pads of the substrate, each bonding agent having a bonding agent melting temperature, providing a semiconductor device having a plurality of solder balls, wherein each of the solder balls has a solder melting temperature that is higher than the bonding agent melting temperature, attaching each of the solder balls to a respective bonding agent, and reflowing the bonding agents at a reflow temperature that is higher than the bonding agent melting temperature such that each of the bonding agents bond one of the solder balls to a respective contact pad.

These and other features and advantages of the present invention will be presented in more detail in the following specification of the invention and the accompanying figures, which illustrate by way of example the principles of the invention.

### BRIEF DESCRIPTION OF THE DRAWINGS

The invention, together with further advantages thereof, may best be understood by reference to the following description taken in conjunction with the accompanying drawings in which:

FIG. 1 illustrates a side, cross-sectional view of a semiconductor device as it is positioned for attachment to an electronic substrate, according to one embodiment of the invention.

FIG. 2 illustrates a side, cross-sectional view of the semiconductor device of FIG. 1 after it has been attached to the electronic substrate.

FIG. 3 illustrates an electrical system according to an alternative embodiment of the invention.

### DETAILED DESCRIPTION OF THE INVENTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known operations have not been described in detail so not to unnecessarily obscure the present invention.

The present invention pertains to the use of a low melting temperature bonding agent that allows a solder reflow process to occur at a lower reflow temperature. One area of use includes semiconductor device manufacturing processes where solder materials having high melting temperatures require reflowing. High melting typical lead-free solders can be used in conjunction with this bonding agent. The bonding agent is placed between a solder ball, for example, and a contact surface. The bonding agent is selected to have a melting temperature that is lower than that of the solder ball. Reflow is then performed at a relative low temperature that is high enough for reflowing the bonding agent, yet at the same time, lower than what would be necessary to reflow the solder material. Since, the electrical system is not subjected to the high temperatures necessary for reflowing the solder material, the electronic system experiences less high-temperature related damage.

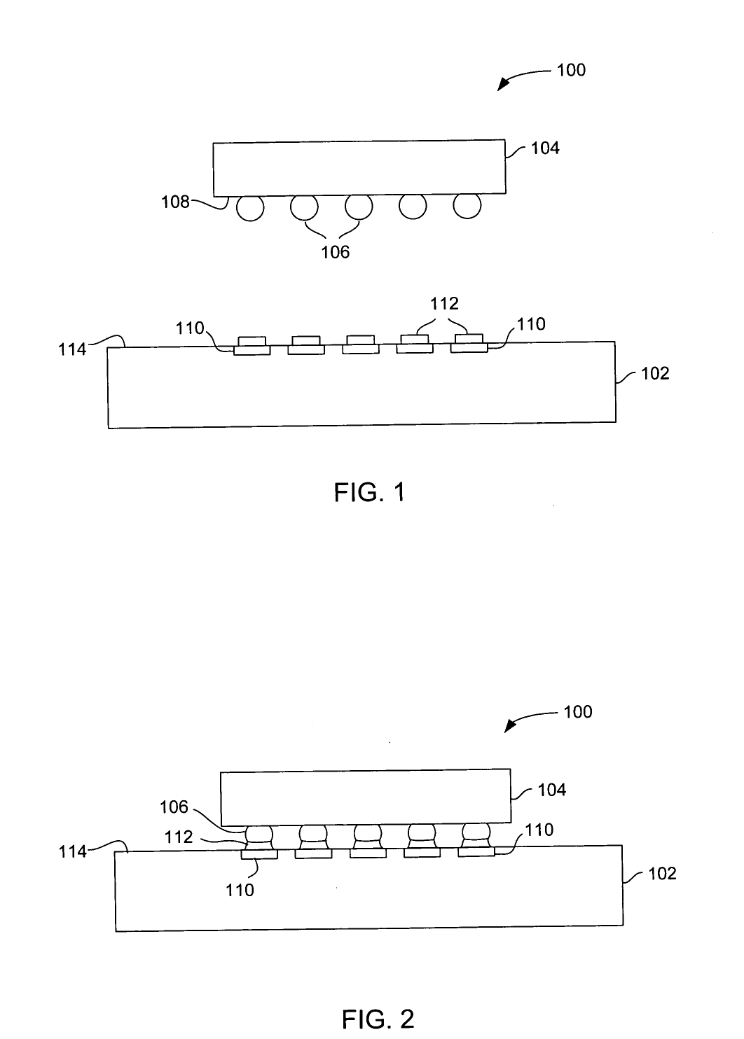

FIGS. 1 and 2 illustrate the use of a bonding agent 112 according to one embodiment of the present invention. FIG. 1 illustrates a side, cross-sectional view of a semiconductor device 100 as it is positioned for attachment to an electronic substrate 102. FIG. 2 illustrates a side, cross-sectional view of semiconductor device 100 after it has been attached to electronic substrate 102.

Semiconductor device 100 includes a semiconductor die 104 and solder balls 106. Semiconductor die 104 is a piece of semiconductor material that contains integrated circuits. Semiconductor die 104 is commonly one many dice that are cut out of a semiconductor wafer. Semiconductor die 104 can have various shapes and sizes. For example, die 104 can have a square shape or an elongated rectangular shape.

Solder balls 106 are formed on a bottom surface 108 of semiconductor die 104 and provide electrical connectivity to integrated circuits within die 104. Bottom surface 108 of die 104 is also referred to as the active surface 108 since it contains the active integrated circuit devices. Solder balls 106 are typically formed upon input/output pads formed on bottom surface 108 of die 104. For the sake of describing the invention, the input/output pads of die 104 are not shown in the figures. Solder balls 106 are formed of an electrically conductive material such as a metal or a metal alloy. As described earlier, solder materials are now commonly formed on lead-free materials to comply with industry standards and new regulations. One metal alloy that forms solder balls 106 includes a combination of tin, silver and copper. Other metal alloys that can also form solder balls 106 include Tin/Silver and Tin/Bismuth. In some embodiments, solder balls 106 can be formed out of any single one of the prior mentioned metals. These lead-free solder balls 106 tend to have higher melting temperatures than solder balls that contain lead. Lead-free solder balls 106 typically have a melting temperature in the range of 215-235° C., depending upon the specific alloy composition of a ball. In other embodiments, the solder balls have a melting temperature in the range of 183-310° C.

Solder balls 106 have a diameter approximately in the range of approximately 80-120 ums. The size of solder balls 106 is not limited to this range however, as the size of solder balls 106 depends upon the type and size of semiconductor device 100. The number of solder balls 106 on semiconductor die 104 also depends upon the specific type and size of device 100. Some semiconductor devices 100 contain a solid array or rows and columns of solder balls 106 that cover a substantial portion of bottom surface 108. Other semiconductor devices 100 have solder balls 106 that are arranged along the outer perimeter of device 100 while the internal area of bottom surface 108 is left uncovered. In these embodiments, the internal area may be occupied by the active integrated circuits.

Electronic substrate 102 is a substrate that contains electrically conductive contact pads 110 and electrically conductive traces that run throughout the substrate. Bonding agent 112 is applied to each surface of contact pads 110. Contact pads 110 are positioned on the top surface 114 of substrate 102. Contact pads 110 and solder balls 106 are arranged to match up to each other when semiconductor device 100 is brought into contact with substrate 102. The spacing or pitch between the solder balls 106 and contact pads 110 should therefore be at least approximately equal. Each contact pad 110 has a surface area that is large enough to support a solder ball 106. The surface area of each contact pads 110 can have outline shapes such as rectangular, square, oval, circle, and so forth. Contact pads 110 of FIG. 1 are flush with the top surface 114 of substrate 102. In alternative embodiments, contact pads 110 can rise above top surface 114 of substrate 102. Contact pads 110 can be formed of different types of conductive materials such as copper, nickel, and gold.

The structure and pattern of the traces are commonly known and therefore are not shown so that the figures can more clearly show bonding agents 112. The conductive traces run through or on the surfaces of substrate 102 to provide electrical connectivity between different electronic circuits and devices. Conductive traces can connect points on opposing surfaces of substrate 102. Commonly vias, vertically positioned pathways, connect conductive traces on opposing surfaces of substrate 102. In some embodiments, substrate 102 is formed of multiple layers that are laminated together. In these embodiments, vias may connect conductive traces on various layers throughout substrate 102.

Bonding agent 112 is a formation of electrically conductive material applied on top of each contact pad 110. Bonding agent 112 has a melting temperature that is lower than that for solder balls 106. Bonding agent 112 is applied to cover an area of each contact pad 110 where a solder ball 106 would make contact with the contact pad 110. Bonding agent 112 may cover the entire surface of a contact pad 110 or it may cover less than the entire surface. In some embodiments, bonding agent 112 covers approximately 90-95% of the surface area of each contact pad 110. The amount of bonding agent 112 applied to each contact pad 112 allows bonding agent 112 to be reflowed and cured to secure a solder ball 106 onto a contact pad 112. It should be noted that bonding agent 112 rises above solder masks applied to the top surface 114 of substrate 102.

Bonding agent 112 may be formed of different conductive materials having a melting temperature that is less than that of the solder balls 106. The temperature required to reflow bonding agent 112 is also less than the temperature required to reflow solder balls 106. Typically, a material is reflowed at a reflow temperature that is above the material's melting temperature to more quickly soften the material. In some embodiments, the reflow temperature for bonding agents 112 is approximately equal to or greater than the melting temperature of solder balls 106. The reflow temperature for bonding agents 112 should be less than the reflow temperature for the solder balls 106 in order to take advantage of reflowing bonding agent 112 at a lower temperature. Solder balls 106 with a melting temperature of approximately 220° C. may require a reflow process to occur at 260° C.

Bonding agent 112 may be formed of metals, metal alloys, and solder materials such as, but not limited to, a, tin/silver/copper (Sn/Ag/Cu), tin/silver (Sn/Ag). The composition of bonding agent 112 also forms a strong bond with the material of contact pads 110 and solder balls 106.

The melting temperature of a bonding agent 112 formed of Sn/Bi or Sn/In has a melting temperature in the range of approximately 115-140° C., depending upon the specific percentage composition of each material. The melting temperature of bonding agent 112 may be above or below the range of 115-140° C.

FIG. 1 illustrates substrate 102 after bonding agent 112 is applied to each contact pad 110. FIG. 2 illustrates substrate 102 after solder balls 106 of semiconductor device 100 are attached to respective bonding agents 112. The combination of semiconductor device 100 and substrate 102 is then subjected to elevated temperatures to reflow bonding agent 112. During the reflow process, bonding agent 112 softens and/or liquefies to wet onto contact pads 110 and solder balls 106. Then a cooling process allows each bonding agent 112 to harden and fixedly attach itself to a solder ball 106 and a contact pad 110. As a result, semiconductor device 100 is secured to substrate 102. Optional operations for injecting an underfill between die 104 and substrate 102, and between solder balls 106 may be performed as well.

Bonding agents 112 thereby attach solder balls 106 to contact pads 110 while requiring the device 104 and substrate 102 combination to be subjected to temperatures necessary to reflow bonding agents 112. A temperature for reflowing bonding agents 112 is at or higher than the melting temperature of bonding agent 112. Bonding agent 112 has a melting temperature that is lower than that of each of solder balls 106. Again, this allows a reflow process to occur within a temperature range that is sufficiently high to reflow bonding agents 112, yet lower than the temperature necessary to reflow solder balls 106. Note that in some reflow processes, the reflow temperature for bonding agents 112 can rise to and above that of the melting temperature of solder balls 106. However, the bonding agent reflow temperature is still lower than the temperature required to reflow solder balls 106. Therefore, bonding agent 112 allows semiconductor device 100 to be attached to substrate 102 at lower and safer processing temperatures. The reflow temperature for bonding agents 112 is designed to be less than the glass transition temperature, T_{g}, of substrate 102 and any other substrates that form a specific electrical system. In some embodiments, substrate 102 is formed of an organic material. The T_{g} of common organic substrate materials is approximately 150° C.

FIG. 2 shows bonding agents 112 of FIG. 2 in their respective shapes after a reflow process has been performed.

In alternative embodiments, semiconductor device 100 can be any type of device that has solder balls for connective purposes. For example, semiconductor device 100 may be a ball grid array device or a flip chip. Ball grid array devices commonly include a semiconductor die that is wire bonded to a substrate wherein the substrate connects the wires to an array of solder balls. As described with respect to FIG. 1, flip chips commonly include solder balls that are directly attached to an active surface of a semiconductor die. Other types of semiconductor devices that include solder balls include wire bonded ball grid array semiconductor packages.

Note that the bonding agent can be used in combination with various types of solder balls that have high melting temperatures. The use of bonding agent is therefore not limited to solder balls that are necessarily lead-free. In some embodiments, bonding agent 112 is formed upon some but not all of contact pads 110 of substrate 102. This is the case when some solder balls may have a relatively low melting temperature such that the bonding agent is not necessary.

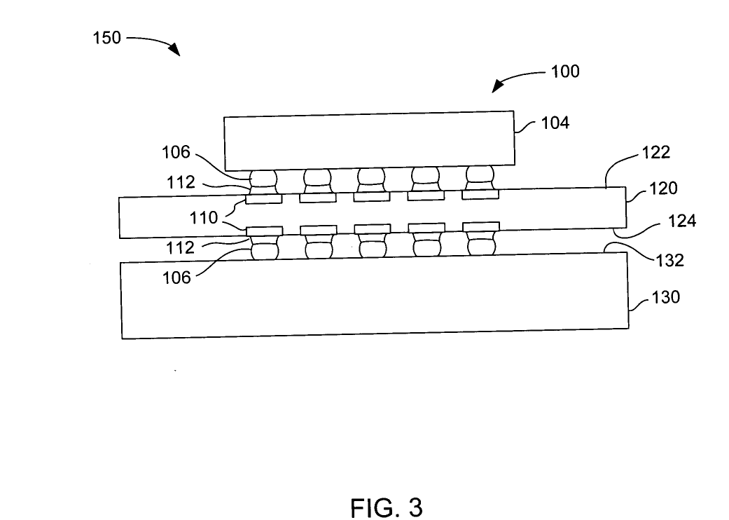

FIG. 3 illustrates an electrical system 150 according to an alternative embodiment of the invention. Electrical system 150 includes a semiconductor device 100, a first electrical substrate 120, and a second electrical substrate 130. Substrate 120 has conductive contact pads 110 on each of its top and bottom surfaces 122 and 124, respectively. Bonding agents 112 are bonded to each of contact pads 110 and connect to solder balls 106 of each of semiconductor device 100 and second substrate 130. Bonding agents 112 are shown in a state after they have been reflowed and cured. The reflow process wets each bonding agent 112 onto each contact pad 110 and respective solder ball 106. Bonding agent 112 has a melting temperature that is lower than that of each of solder balls 106. Again, this allows electrical system 150 to be subjected to a reflow process within a temperature range that is sufficiently high to reflow bonding agents 112. However, this temperature range is lower than the temperature necessary to reflow solder balls 106 and therefore electrical system 150 need not be subjected to extremely high reflow process temperatures where it could be damaged. Note that in some reflow processes, the reflow temperature for bonding agents 112 can rise to and above that of the melting temperature of solder balls 106. However, the bonding agent reflow temperature is still lower than the temperature required to reflow solder balls 106.

Semiconductor device 100 includes a semiconductor die 104 and solder balls 106.

Bonding agent 112 is selected of a material that is capable of wetting onto each of contact pads 110 and solder balls 106. In some embodiments, bonding agent 112 may not wet and bond to one or both of solder balls 106 and contact pads 110. In these cases, an additional layer of material is necessary to form a connection between bonding agent 112 and one or both of contact pads 10 and solder balls 106. The additional layer of material is selected for its ability to wet onto solder balls 106 and/or contact pads 110.

Solder balls 106 are initially formed on each of semiconductor device 100 and second substrate 130. Semiconductor device 100 and second substrate 130 are then positioned so that each other their respective solder balls 106 are placed in contact with contact pads 110. In alternative embodiments, solder balls 106 may be formed on a surface of first substrate 120. In such embodiments, the solder balls of first substrate 120 are then placed in contact with a bonding agent 112 that is formed on a contact pad of another electrical device or substrate.

Contact pads 110 are connected to electrically conductive pathways that are formed of, for example, vias and traces. The vias and traces interconnect various contact pads 110 on either the same or different surfaces 122 and 124 of first substrate 120 to connect electrical devices. First substrate 120 is an interposer used for reducing the stress imposed upon second substrate 130 by semiconductor device 100, and vice-versa. Second substrate 130 and semiconductor device 100 may impose stress upon each other due to mismatches in compositional characteristics. For example, mismatches in coefficients of thermal expansion may cause each of semiconductor device 100 and second substrate 130 to change size at different rates and thereby push and pull upon each other until electrical system 150 is structurally damaged. First substrate 120 (or interposer) protects electrical system 150 from such damage by absorbing the stresses imposed by semiconductor device 100 and second substrate 130. The thickness of first substrate 120 may vary depending upon, for example, the amount of vias and traces embedded within, the amount of stress required to be absorbed. First substrate 120 may be formed of multiple layers of material that are laminated together.

First substrate 120 may be formed of materials such as but not limited to FR4, BT(Bismaliemide Triazine), FR5, and Polyimide.

Second substrate 130 is another electrical substrate that contains electrically conductive pathways. Solder balls 132 are formed on the top surface 132 of second substrate 130. Second substrate 130 may be, for example, a printed circuit board. In an alternative embodiment, second substrate 130 also contains contact pads. These contact pads provide connection to other semiconductor devices, for example. These other semiconductor devices attached to second substrate 130 directly, in other words, without the intermediate connection through first substrate 120.

In some embodiments, second substrate 130 may be replaced with another semiconductor device such that first substrate 120 would interconnect multiple semiconductor devices.

In yet other embodiments, bonding agents 112 may facilitate the connection between solder balls of a first semiconductor device and the contact pads of a second semiconductor device. The contact pads may be formed on the top surface of the second semiconductor device. Such semiconductor devices are then positioned on top of each other to form a stacked device configuration.

In some embodiments, a bonding agent may be placed over a solder ball instead of being placed over a contact pad. The solder ball is then positioned so that the bonding agent makes contact with a contact pad. A reflow process then secures the solder ball to the contact pad.

The bonding agent of the present invention can facilitate bonding any two types of components, whether electrical in nature or not, through solder material.

While this invention has been described in terms of several preferred embodiments, there are alteration, permutations, and equivalents, which fall within the scope of this invention. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

We claim:

1. An electrical system comprising:
a substrate having contact pads and conductive traces, at least some of the contact pads being connected to a respective conductive trace;
a bonding agent formed upon at least some of the contact pads, each bonding agent having a bonding agent melting temperature; and
a semiconductor device having a plurality of solder balls, each of the solder balls being attached to a respective bonding agent wherein each bonding agent bonds a solder ball to a contact pad and wherein each of the solder balls has a solder melting temperature that is higher than the bonding agent melting temperature.

2. An electrical system as recited in claim 1 wherein the bonding agent melting temperature is approximately in the range of 115-140° C.

3. An electrical system as recited in claim 1 wherein the solder melting temperature is in the range of approximately 183-310° C.

4. An electrical system as recited in claim 1 wherein the bonding agent is a tin and bismuth alloy.

5. An electrical system as recited in claim 1 wherein the bonding agent is a tin and indium alloy.

6. An electrical system as recited in claim 1 wherein the solder balls are formed of a lead-free material.

7. An electrical system as recited in claim 6 wherein the solder balls are formed of a tin, silver, and copper alloy.

8. An electrical system as recited in claim 1 wherein the semiconductor device is a flip chip or a ball grid array semiconductor device.

9. An electrical system as recited in claim 1 wherein the substrate is a printed circuit board.

10. An electrical system as recited in claim 1 wherein the substrate is an interposer.

11. An electrical system comprising:
a first substrate having contact pads and conductive traces formed upon a first surface and an opposing second surface, at least some of the contact pads being connected to a respective conductive trace;
a bonding agent formed upon at least some of the contact pads of the first and the second surface of the first substrate, each of the bonding agents having a bonding agent melting temperature;
a semiconductor device having a plurality of solder balls, each of the solder balls being attached to a respective bonding agent on the first surface of the first substrate wherein each bonding agent bonds a solder ball to a contact pad; and
a second substrate having a plurality of solder balls, each of the solder balls being attached to a respective bonding agent on the second surface of the first substrate wherein each bonding agent bonds a solder ball to a contact pad,
wherein the solder balls of the semiconductor device and the second substrate have a solder melting temperature that is higher than the bonding agent melting temperature.

12. An electrical system as recited in claim 11 wherein the bonding agent is a tin and bismuth alloy.

13. An electrical system as recited in claim 11 wherein the bonding agent is a tin and indium alloy.

14. An electrical system as recited in claim 11 wherein the solder balls are formed of a lead-free material.

15. An electrical system as recited in claim 11 wherein the first substrate is an interposer and the second substrate is a printed circuit board.

16. An electrical system comprising:
a first electrical device having contact pads and conductive traces, at least some of the contact pads being connected to a respective conductive trace;
a bonding agent formed upon at least some of the contact pads of the first electrical device, each bonding agent having a bonding agent melting temperature; and
a second electrical device having a plurality of solder balls, each of the solder balls being attached to a respective bonding agent wherein each bonding agent bonds a solder ball to a contact pad of the first electrical device and wherein each of the solder balls has a solder melting temperature that is higher than the bonding agent melting temperature.

17. An electrical system as recited in claim 16 wherein the bonding agent melting temperature is approximately in the range of 115-140° C.

18. An electrical system as recited in claim 16 wherein the solder melting temperature is in the range of approximately 183-310° C.

19. An electrical system as recited in claim 16 wherein the bonding agent is a tin and bismuth alloy.

20. An electrical system as recited in claim 16 wherein the bonding agent is a tin and indium alloy.

21. An electrical system as recited in claim 16 wherein the solder balls are formed of a lead-free material.

22. An electrical system as recited in claim 16 wherein the first electrical device is a printed circuit board and the second electrical device is a flip chip or a ball grid array semiconductor device.

23. An electrical system as recited in claim 16 wherein the first electrical device is a first electrical substrate and the second electrical device is a second electrical substrate.

24. An electrical system as recited in claim 16 wherein the first electrical device is an interposer substrate and the second electrical device is a printed circuit board.

25. An electrical system as recited in claim 16 wherein the first electrical device is a first semiconductor device and the second electrical device is a second semiconductor device.

26. A method for manufacturing an electrical system comprising:
providing a substrate having contact pads and conductive traces, at least some of the contact pads being connected to a respective conductive trace;
applying a bonding agent upon at least some of the contact pads of the substrate, each bonding agent having a bonding agent melting temperature;
providing a semiconductor device having a plurality of solder balls, wherein each of the solder balls has a solder melting temperature that is higher than the bonding agent melting temperature;
attaching each of the solder balls to a respective bonding agent; and
reflowing the bonding agents at a reflow temperature that is higher than the bonding agent melting temperature such that each of the bonding agents bond one of the solder balls to a respective contact pad.

27. A method as recited in claim 26 further comprising:
curing each of the bonding agents to allow the bonding agents to solidify and thereby fixedly attach to each of a solder ball and a contact pad.

28. A method as recited in claim 26 wherein the reflow temperature is lower than the solder melting temperature.

29. A method as recited in claim 26 wherein the bonding agent melting temperature is approximately in the range of 115-140° C.

30. A method as recited in claim 26 wherein the solder melting temperature is in the range of approximately 183° C.-310° C.

31. A method as recited in claim 26 wherein the bonding agent is a tin and bismuth alloy.

32. A method as recited in claim 26 wherein the bonding agent is a tin and indium alloy.

33. A method as recited in claim 26 wherein the solder balls are formed of a lead-free material.
